(19) United States
(12) Patent Application Publication
(10) Pub. No.: US 2024/0290931 A1
(43) Pub. Date: Aug. 29, 2024

(54) DISPLAY DEVICE

(71) Applicant: LG Display Co., Ltd., Seoul (KR)

(72) Inventors: Eunjeong YANG, Goyang-si (KR); SeungBum HEO, Incheon (KR)

(21) Appl. No.: 18/589,218

(22) Filed: Feb. 27, 2024

(30) Foreign Application Priority Data
Feb. 28, 2023 (KR) 10-2023-0026809

(51) Int. Cl. H01L 33/64; H01L 25/075; H01L 33/62; H05K 7/20

(52) U.S. Cl. CPC H01L 33/642; H01L 25/0753; H01L 33/62; H05K 7/20963

(57) ABSTRACT

A display device according to an exemplary embodiment of the present disclosure includes a display panel in which an active area and a non-active area are defined. The display device includes a cover bottom which supports the display panel on a rear surface of the display panel. The display device includes a plate bottom disposed in an opening of the cover bottom. The display device includes a printed circuit board disposed on a rear surface of the plate bottom. The display device includes a cover shield disposed to cover the printed circuit board on the rear surface of the cover bottom. A plurality of first vent holes and a plurality of first heat dissipation fins are disposed in a part of the plate bottom, thereby effectively discharging the heat of a heat generating unit.

### CROSS-REFERENCE TO RELATED APPLICATIONS

This application claims the priority of Korean Patent Application No. 10-2023-0026809 filed on Feb. 28, 2023, in the Korean Intellectual Property Office, the disclosure of which is incorporated herein by reference.

### BACKGROUND

### Technical Field

The present disclosure relates to a display device, and more particularly, to a display device using a light emitting element such as a light emitting diode (LED).

### Description of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast-lighting speed, excellent luminous efficiency, and a strong impact resistance so that a stability is excellent and an image having a high luminance can be displayed.

### BRIEF SUMMARY

Various embodiments of the present disclosure provide a display device which protects a printed circuit board and reduces a temperature of a high heat portion of a front surface of a display panel of the display device.

Various embodiments of the present disclosure provide a display device which suppresses concentration of the heat on a specific portion of a plate bottom.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a display panel in which an active area and a non-active area are defined, a cover bottom which supports the display panel on a rear surface of the display panel, a plate bottom disposed in an opening of the cover bottom, a printed circuit board disposed on a rear surface of the plate bottom and a cover shield disposed to cover the printed circuit board on the rear surface of the cover bottom, and a plurality of first vent holes and a plurality of first heat dissipation fins may be disposed in a part of the plate bottom.

According to another aspect of the present disclosure, a display device includes a display panel in which an active area and a non-active area are defined, a cover bottom which supports the display panel on a rear surface of the display panel, a plate bottom disposed in a lower end of the cover bottom, a printed circuit board disposed on a rear surface of the plate bottom to be covered by the lower end of the cover bottom, and a plurality of first vent holes and a plurality of first heat dissipation fins may be disposed in a part of the plate bottom and a plurality of second vent holes and a plurality of second heat dissipation fins may be disposed in a lower end of the cover bottom.

According to yet another aspect of the present disclosure, a tiling display device includes a plurality of display units, wherein each of the display units comprises the display device as described above.

Other detailed matters of the exemplary embodiments are included in the detailed description and the drawings.

According to the present disclosure, a vent hole and a heat dissipation fin for dissipating heat are configured on a cover shield and a plate bottom to protect the printed circuit board and effectively discharge heat of a heat generating unit.

According to the present disclosure, a cover shield is integrally formed on a cover bottom to improve a heat dissipation effect and simplify a component material with a uni-material.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is a plan view of a display panel according to an exemplary embodiment of the present disclosure;

FIG. 4 is a cross-sectional view of a display device according to an exemplary embodiment of the present disclosure;

FIG. 5 is an exploded perspective view of a display device according to an exemplary embodiment of the present disclosure;

FIG. 6 is a rear view of a display device according to an exemplary embodiment of the present disclosure;

FIG. 7 is an enlarged perspective view of a cover shield of FIG. 6;

FIG. 8 is an enlarged perspective view of a plate bottom of FIG. 6;

FIG. 9A is a simulation result of a temperature distribution of a heat generating unit according to a comparative embodiment;

FIG. 9B is a simulation result of a temperature distribution of a heat generating unit according to an exemplary embodiment;

FIG. 10A is a simulation result of a temperature of a front surface of a display device according to a comparative embodiment;

FIG. 10B is a simulation result of a temperature of a front surface of a display device according to an exemplary embodiment;

FIG. 11 is an exploded perspective view of a display device according to another exemplary embodiment of the present disclosure;

FIG. 12 is a rear view of a display device according to another exemplary embodiment of the present disclosure; and

FIG. 13 is an enlarged perspective view of a part A of FIG. 12.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, the element or layer may be disposed on the other element or layer directly, or another layer or another element may be interposed therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

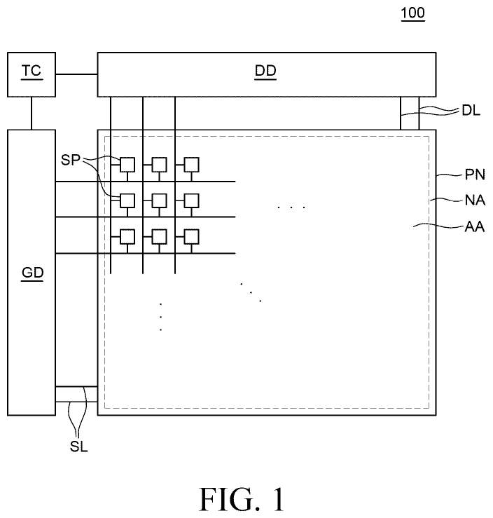

FIG. 1 is a schematic diagram of a display device according to an exemplary embodiment of the present disclosure.

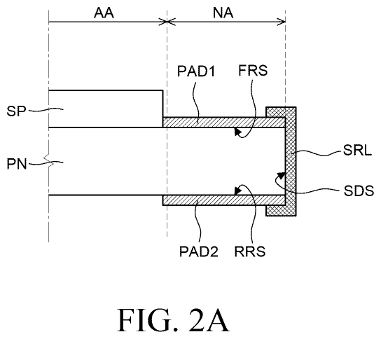

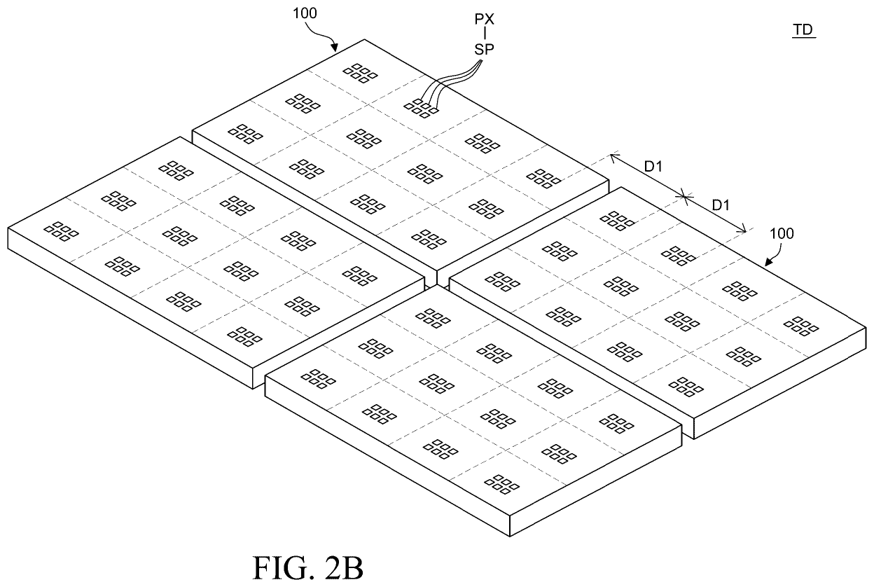

FIG. 2A is a partial cross-sectional view of a display device according to an exemplary embodiment of the present disclosure.

FIG. 2B is a perspective view of a tiling display device according to an exemplary embodiment of the present disclosure.

In FIG. 1, for the convenience of description, among various components of the display device 100, only a display panel PN, a gate driver GD, a data driver DD, and a timing controller TC are illustrated.

Referring to FIG. 1, the display device 100 according to an exemplary embodiment of the present disclosure may include a display panel PN including a plurality of sub pixels SP, a gate driver GD and a data driver DD which supply various signals to the display panel PN, and a timing controller TC.

The gate driver GD may supply a plurality of scan signals to a plurality of scan lines SL in accordance with a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD may convert image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and may include the plurality of sub pixels SP. In the display panel PN, the plurality of scan lines SL and the plurality of data lines DL intersect each other and the plurality of sub pixels SP may be connected to the scan lines SL and the data lines DL, respectively. In addition, even though it is not illustrated in the drawing, each of the plurality of sub pixels SP may be connected to a high potential power line, a low potential power line, a reference line, and the like.

In the display panel PN, an active area AA and the non-active area NA enclosing the active area AA may be defined.

The active area AA is an area in which images are displayed in the display device 100.

In the active area AA, a plurality of sub pixels SP which configures a plurality of pixels and a circuit for driving the plurality of sub pixels SP may be disposed. The plurality of sub pixels SP is a minimum unit which configures the active area AA and n sub pixels SP may form one pixel. In each of the plurality of sub pixels SP, a light emitting element and a thin film transistor for driving the light emitting element may be disposed. The plurality of light emitting elements may be defined in different manners depending on the type of the display panel PN. For example, when the display panel PN is an inorganic light emitting display panel, the light emitting element may be a light emitting diode (LED) or a micro light emitting diode (LED).

In the active area AA, a plurality of wiring lines which transmits various signals to the plurality of sub pixels SP may be disposed. For example, the plurality of wiring lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL extends in one direction in the active area AA to be connected to the plurality of sub pixels SP and the plurality of data lines DL extends in a direction different from the one direction in the active area AA to be connected to the plurality of sub pixels SP. In addition, in the active area AA, a low potential power line, a high potential power line, and the like may be further disposed, but are not limited thereto.

The non-active area NA is an area where no image is displayed. The non-active area NA may be defined as an area extending from the active area AA. In the non-active area NA, a link line which transmits a signal to the sub pixel SP of the active area AA, a pad electrode, a driving IC, such as a gate driver IC or a data driver IC, or the like may be disposed.

In the meantime, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board. The data driver DD and the timing controller TC may be electrically connected to the display panel PN by bonding the flexible film and the printed circuit board to the pad electrode formed in the non-active area NA of the display panel PN.

If the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel may be increased.

In contrast, when the gate driver GD is mounted in the active area AA in the GIA manner and a side line which connects the signal line on the front surface of the display panel PN to the pad electrode on a rear surface of the display panel PN is formed to bond the flexible film and the printed circuit board onto a rear surface of the display panel PN, the non-active area NA may be reduced or minimized on the front surface of the display panel PN. That is, when the gate driver GD, the data driver DD, and the timing controller TC are connected to the display panel PN as described above, a zero bezel with substantially no bezel may be implemented.

For example, referring to FIGS. 2A and 2B, in the non-active area NA of the display panel PN according to an exemplary embodiment of the present disclosure, a plurality of pad electrodes for transmitting various signals to the plurality of sub pixels SP may be disposed. For example, in the non-active area NA on the front surface FRS of the display panel PN, a first pad electrode PAD1 which transmits a signal to the plurality of sub pixels SP may be disposed. In the non-active area NA on the rear surface RRS of the display panel PN, a second pad electrode PAD2 which is electrically connected to a driving component, such as a flexible film and the printed circuit board, may be disposed. That is, on the front surface FRS of the display panel PN on which images are displayed, only a pad area of the non-active area NA in which the first pad electrode PAD1 is disposed may be formed at minimum. Further, as shown in FIG. 2A, an end of the first pad electrode PAD1 partially extends into the active area AA of the display panel PN from a plan view to electrically connect with the sub pixels SP in the active area AA.

In this case, even though it is not illustrated in the drawing, various signal lines connected to the plurality of sub pixels SP, for example, a scan line, a data line, or the like extends from the active area AA to the non-active area NA to be electrically connected to the first pad electrode PAD1.

The side line SRL may be disposed along a side surface SDS of the display panel PN. The side line SRL may electrically connect a first pad electrode PAD1 on the front surface FRS of the display panel PN and a second pad electrode PAD2 on the rear surface RRS of the display panel PN. Therefore, a signal from a driving component on the rear surface RRS of the display panel PN may be transmitted to the plurality of sub pixels SP through the second pad electrode PAD2, the side line SRL, and the first pad electrode PAD1.

As described above, a signal transmitting path from the front surface FRS of the display panel PN to the side surface SDS and the rear surface RRS is formed to reduce or minimize an area of the non-active area NA on the front surface FRS of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image is not displayed between the display devices 100 is minimized or reduced so that a display quality may be improved.

For example, the plurality of sub pixels SP may configure one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, a distance D1 between pixels PX between the display devices 100 is constantly configured to reduce or minimize the seam area.

However, FIGS. 2A and 2B are illustrative so that the display device 100 according to the exemplary embodiment of the present disclosure may be a general display device 100 with a bezel, but is not limited thereto.

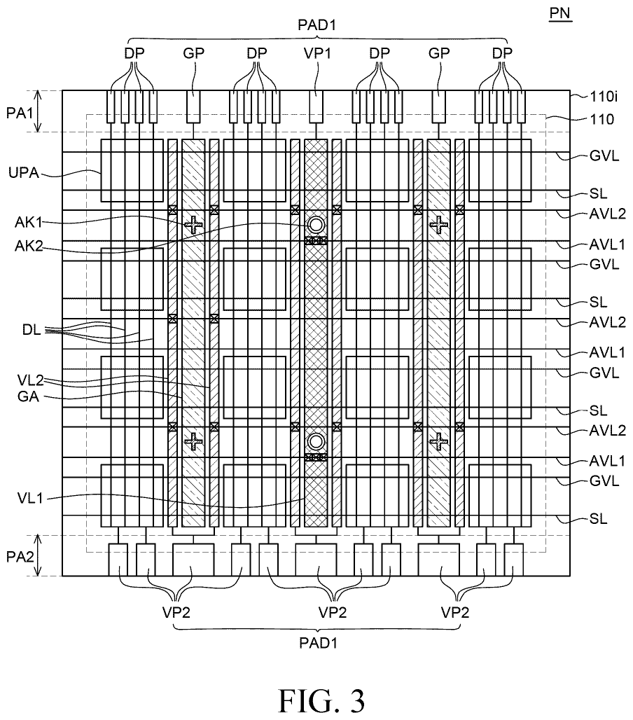

FIG. 3 is a plan view of a display panel according to an exemplary embodiment of the present disclosure.

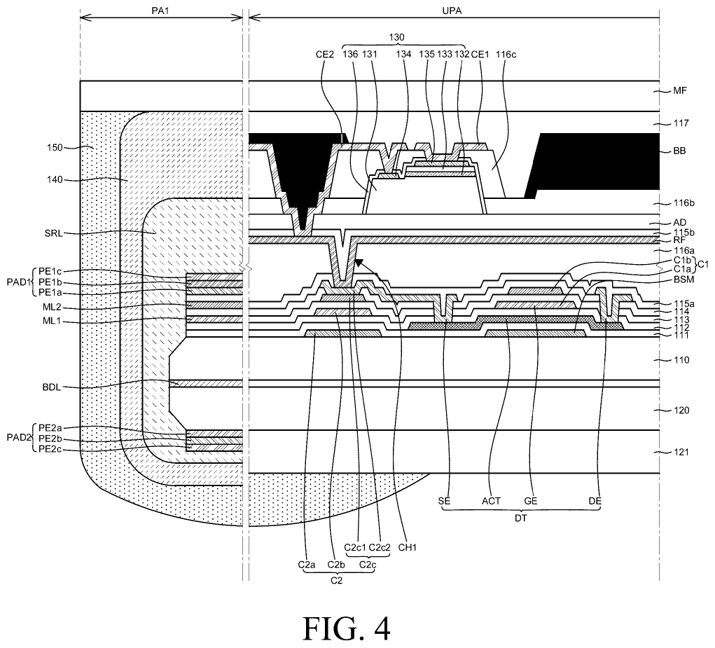

FIG. 4 is a cross-sectional view of a display device according to an exemplary embodiment of the present disclosure.

First, referring to FIGS. 3 and 4, the display panel PN may include a first substrate 110.

The first substrate 110 is a substrate which supports components disposed above the first substrate 110 and may be an insulating substrate.

A plurality of pixels PX is formed on the first substrate 110 to display images. For example, the first substrate 110 may be formed of glass or resin. Further, the first substrate 110 may include polymer or plastic. In some exemplary embodiments, the first substrate 110 may be formed of a plastic material having flexibility.

In the first substrate 110, a plurality of pixel areas UPA, a plurality of gate driving areas GA, and a plurality of pad areas PA1 and PA2 may be disposed. Among them, the plurality of pixel areas UPA and the plurality of gate driving areas GA may be included in the active area AA of the display panel PN.

First, the plurality of pixel areas UPA is areas in which the plurality of pixels PX is disposed.

The plurality of pixel areas UPA may be disposed by forming a plurality of rows and a plurality of columns. Each of the plurality of pixels PX disposed in the plurality of pixel areas UPA may include a plurality of sub pixels SP. Each of the plurality of sub pixels SP includes a light emitting element 130 and a pixel circuit to independently emit light. The plurality of sub pixels SP may include a plurality of sub pixels SP which emits different color light. For example, the plurality of sub pixels SP may include a red sub pixel, a blue sub pixel, and a green sub pixel, but is not limited thereto.

The plurality of gate driving areas GA is areas where gate drivers GD are disposed.

The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

At this time, the gate driver GD disposed in the gate driving area GA may include a circuit for outputting a scan signal. The gate driver GD may include a plurality of transistors and/or capacitors. Here, active layers of the plurality of transistors may be formed of a semiconductor material, such as an oxide semiconductor, amorphous silicon, or polysilicon, but are not limited thereto. Further, the active layers of the plurality of transistors may be formed of the same material or different materials from each other. Further, the active layers of the plurality of transistors of the gate driver may be formed of the same material as active layers of various transistors of the pixel circuit or formed of different materials from each other.

The plurality of pad areas PA1 and PA2 is areas in which a plurality of first pad electrodes PAD1 is disposed.

The plurality of first pad electrodes PAD1 may transmit various signals to various wiring lines extending in a column direction in the active area AA. For example, the plurality of first pad electrodes PAD1 may include a data pad DP, a gate pad GP, a high potential power pad VP1, and a low potential power pad VP2. The data pad DP transmits a data voltage to the data line DL and the gate pad GP transmits a clock signal, a start signal, a gate low voltage, a gate high voltage, and the like for driving the gate driver GD to the gate driver GD. The high potential power pad VP1 transmits a high potential power voltage to the high potential power line VL1 and the low potential power pad VP2 transmits a low potential power voltage to the low potential power line VL2.

The plurality of pad areas PA1 and PA2 may include a first pad area PA1 located at an upper edge of the display panel PN and a second pad area PA2 of the display panel PN. At this time, in the first pad area PA1 and the second pad area PA2, different types of first pad electrodes PAD1 may be disposed. For example, in the first pad area PA1, among the plurality of first pad electrodes PAD1, the data pad DP, the gate pad GP, and the high potential power pad VP1 may be disposed and in the second pad area PA2, the low potential power pad VP2 may be disposed.

At this time, the plurality of first pad electrodes PAD1 may be formed to have different sizes, respectively. For example, the plurality of data pads DP which is connected to the plurality of data lines DL one to one may have a narrower width and the high potential power pad VP1, the low potential power pad VP2, and the gate pad GP may have a larger width. However, widths of the data pad DP, the gate pad GP, the high potential power pad VP1, and the low potential power pad VP2 illustrated in FIG. 3 are illustrative so that the first pad electrode PAD1 may be configured in various sizes, but is not limited thereto.

In order to reduce the bezel of the display panel PN, an edge of the display panel PN may be cut to be removed. The plurality of pixels PX, the plurality of wiring lines, and the plurality of first pad electrodes PAD1 are formed on an initial first substrate 110i and an edge part of the initial first substrate 110i is ground to reduce the bezel area. That is, for example, during the grinding process, a part of the initial first substrate 110i is removed to form a first substrate 110 with a smaller size. At this time, parts of the plurality of first pad electrodes PAD1 and wiring lines disposed at the edge of the first substrate 110 may be removed. Accordingly, only a part of the plurality of first pad electrodes PAD1 may remain on the first substrate 110.

Next, the plurality of data lines DL which extends in a column direction from the plurality of first pad electrodes PAD1 may be disposed on the first substrate 110 of the display panel PN. The plurality of data lines DL may extend from the plurality of data pads DP of the first pad area PA1 toward the plurality of pixel areas UPA. The plurality of data lines DL may extend in a column direction and overlap the plurality of pixel areas UPA. Therefore, the plurality of data lines DL may transmit the data voltage to the pixel circuit of each of the plurality of sub pixels SP.

The plurality of high potential power lines VL1 extending in the column direction may be disposed on the first substrate 110 of the display panel PN. Some of the plurality of high potential power lines VL1 extends from the high potential power pad VP1 of the first pad area PA1 to the plurality of pixel areas UPA to transmit the high potential power voltage to the light emitting elements 130 of the plurality of sub pixels SP, respectively. The others of the plurality of high potential power lines VL1 may be electrically connected to the other high potential power line VL1 by means of an auxiliary high potential power line AVL1 to be described below. In FIG. 3, for the convenience of description, even though it is illustrated that one high potential power line VL1 and one high potential power pad VP1 are disposed, a plurality of high potential power lines VL1 and high potential power pads VP1 may be disposed.

The plurality of low potential power lines VL2 extending in the column direction may be disposed on the first substrate 110 of the display panel PN. For example, at least some of the plurality of low potential power lines VL2 extends from the low potential power pad VP2 of the second pad area PA2 to the plurality of pixel areas UPA to transmit the low potential power voltage to the pixel circuit of each of the plurality of sub pixels SP. The others of the plurality of low potential power lines VL2 may be electrically connected to the other low potential power line VL2 by means of an auxiliary low potential power line AVL2.

The plurality of scan lines SL extending in the row direction may be disposed on the first substrate 110 of the display panel PN. The plurality of scan lines SL extends in the row direction and may be disposed across the plurality of pixel areas UPA and the plurality of gate driving areas GA. For example, the plurality of scan lines SL may transmit the scan signal from the gate driver GD to the pixel circuits of the plurality of sub pixels SP.

A plurality of auxiliary high potential power lines AVL1 extending in the row direction may be disposed on the first substrate 110 of the display panel PN. For example, the plurality of auxiliary high potential power lines AVL1 may be disposed in an area between the plurality of pixel areas UPA. For example, the plurality of auxiliary high potential power lines AVL1 extending in the row direction is electrically connected to the plurality of high potential power lines VL1 extending in the column direction and may form a mesh structure. Therefore, the plurality of auxiliary high potential power lines AVL1 and the plurality of high potential power lines VL1 are configured to form a mesh structure to minimize voltage drop and voltage deviation.

A plurality of auxiliary low potential power lines AVL2 extending in the row direction may be disposed on the first substrate 110 of the display panel PN. For example, the plurality of auxiliary low potential power lines AVL2 may be disposed in an area between the plurality of pixel areas UPA. The plurality of auxiliary low potential power lines AVL2 extending in the row direction is electrically connected to the plurality of low potential power lines VL2 extending in the column direction through a contact hole to form a mesh structure. Therefore, the plurality of auxiliary low potential power lines AVL2 and the plurality of low potential power lines VL2 are configured to form a mesh structure to reduce a resistance of the wiring line and minimize voltage deviation.

The plurality of gate driving lines GVL extending in the row direction may be disposed on the first substrate 110 of the display panel PN. The plurality of gate driving lines GVL may transmit various signals to the gate driver GD of the gate driving area GA. The plurality of gate driving lines GVL may include wiring lines which transmit a clock signal, a start signal, a gate high voltage, a gate low voltage, and the like to the gate driver GD. Therefore, various signals are transmitted from the gate driving line GVL to the gate driver GD to drive the gate driver GD.

A plurality of alignment keys AK1 and AK2 may be disposed in an area between the plurality of pixel areas UPA in the display panel PN. The plurality of alignment keys AK1 and AK2 is used for alignment during the manufacturing process of the display panel PN. The plurality of alignment keys AK1 and AK2 may include a first alignment key AK1 and a second alignment key AK2.

The first alignment key AK1 may be disposed in the gate driving area GA between the plurality of pixel areas UPA. The first alignment key AK1 may be used to inspect an alignment position of the plurality of light emitting elements 130. For example, the first alignment key AK1 may have a cross shape, but is not limited thereto.

The second alignment key AK2 may be disposed to overlap the high potential power line VL1 between the plurality of pixel areas UPA. In the high potential power line VL1, a hole overlapping the second alignment key AK2 is formed to divide the second alignment key AK2 and the high potential power line VL1. The second alignment key AK2 may be used to align the display panel PN and a donor. The display panel PN and the donor are aligned using the second alignment key AK2 and the plurality of light emitting elements 130 of the donor may be transferred onto the display panel PN. For example, the second alignment key AK2 may have a circular ring shape, but is not limited thereto.

Referring to FIG. 4, the pixel circuit for driving the light emitting element 130 may be disposed in each of the plurality of sub pixels SP on the first substrate 110. The pixel circuit may include a plurality of thin film transistors and a plurality of capacitors. In FIG. 4, for the convenience of description, only a driving transistor DT, a first capacitor C1, and a second capacitor C2, among configurations of the pixel circuit are illustrated. However, the pixel circuit may further include a switching transistor, a sensing transistor, and an emission control transistor, but is not limited thereto.

First, a light shielding layer BSM may be disposed on the first substrate 110.

The light shielding layer BSM blocks light which is incident to an active layer ACT of the plurality of transistors to reduce or minimize a leakage current. For example, the light shielding layer BSM is disposed below the active layer ACT of the driving transistor DT to block light incident onto the active layer ACT. If light is irradiated onto the active layer ACT, leakage current is generated, which deteriorates the reliability of the transistor. Accordingly, the light shielding layer BSM which blocks the light is disposed on the first substrate 110 to improve the reliability of the driving transistor DT. The light shielding layer BSM may be configured by an opaque conductive material such as copper (Cu), aluminum (Al), molybdenum (Mo), nickel (Ni), titanium (Ti), chrome (Cr), or an alloy thereof, but is not limited thereto.

A buffer layer 111 may be disposed on the light shielding layer BSM. The buffer layer 111 may reduce permeation of moisture or impurities through the first substrate 110. For example, the buffer layer 111 may be configured by a single layer or a double layer of silicon oxide SiOx or silicon nitride SiNx, but is not limited thereto. However, the buffer layer 111 may be omitted depending on a type of the first substrate 110 or a type of the thin film transistor, but is not limited thereto.

A driving transistor DT including an active layer ACT, a gate electrode GE, a source electrode SE, and a drain electrode DE may be disposed on the buffer layer 111.

First, the active layer ACT of the driving transistor DT may be disposed on the buffer layer 111. The active layer ACT may be formed of a semiconductor material such as an oxide semiconductor, amorphous silicon, or polysilicon, but is not limited thereto. Further, even though it is not illustrated in the drawings, other transistors, such as a switching transistor, a sensing transistor, and an emission control transistor, other than the driving transistor DT, may be further disposed. The active layers of the transistors may be also formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control transistor, may be formed of the same material, or formed of different materials.

A gate insulating layer 112 may be disposed on the active layer ACT.

The gate insulating layer 112 is an insulating layer which electrically insulates the active layer ACT from the gate electrode GE and may be configured by a single layer or a double layer of silicon oxide SiOx or silicon nitride SiNx, but is not limited thereto.

The gate electrode GE may be disposed on the gate insulating layer 112.

The gate electrode GE may be configured by a conductive material, such as copper (Cu), aluminum (Al), molybdenum (Mo), nickel (Ni), titanium (Ti), chrome (Cr), or an alloy thereof, but is not limited thereto.

A first interlayer insulating layer 113 and a second interlayer insulating layer 114 may be disposed on the gate electrode GE. In the first interlayer insulating layer 113 and the second interlayer insulating layer 114, contact holes through which each of the source electrode SE and the drain electrode DE is connected to the active layer ACT may be formed. The first interlayer insulating layer 113 and the second interlayer insulating layer 114 are insulating layers which protect components therebelow and may be configured by single layers or double layers of silicon oxide SiOx or silicon nitride SiNx, but are not limited thereto.

The source electrode SE and the drain electrode DE which are electrically connected to the active layer ACT may be disposed on the second interlayer insulating layer 114. The source electrode SE may be connected to the second capacitor C2 and the first electrode 134 of the light emitting element 130 and the drain electrode DE may be connected to the other configuration of the pixel circuit. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

Next, the first capacitor C1 may be disposed on the gate insulating layer 112. The first capacitor C1 may include a 1-1-th capacitor electrode C1a and a 1-2-th capacitor electrode C1b.

First, the 1-1-th capacitor electrode C1a may be disposed on the gate insulating layer 112. The 1-1-th capacitor electrode C1a may be integrally formed with the gate electrode GE of the driving transistor DT.

The 1-2-th capacitor electrode C1b may be disposed on the first interlayer insulating layer 113. For example, the 1-2-th capacitor electrode C1b may be disposed to overlap the 1-1-th capacitor electrode C1a with the first interlayer insulating layer 113 therebetween.

The first capacitor C1 is connected to the gate electrode GE of the driving transistor DT to maintain a voltage of the gate electrode GE of the driving transistor DT for a predetermined period.

Next, the second capacitor C2 may be disposed on the first substrate 110. The second capacitor C2 may include a 2-1-th capacitor electrode C2a, a 2-2-th capacitor electrode C2b, and a 2-3-th capacitor electrode C2c. The second capacitor C2 may include the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode.

The 2-1-th capacitor electrode C2a may be disposed on the first substrate 110. The 2-1-th capacitor electrode C2a may be disposed on the same layer as the light shielding layer BSM and may be formed of the same material.

The 2-2-th capacitor electrode C2b may be disposed on the buffer layer 111 and the gate insulating layer 112. The 2-2-th capacitor electrode C2b may be disposed on the same layer as the gate electrode GE and may be formed of the same material.

The 2-3-th capacitor electrode C2c may be disposed on the first interlayer insulating layer 113. The 2-3-th capacitor electrode C2c may be configured by a first layer C2c1 and a second layer C2c2. The first layer C2c1 of the 2-3-th capacitor electrode C2c may be formed on the same layer as the 1-2-th capacitor electrode C1b with the same material. For example, the first layer C2c1 may be disposed to overlap the 2-1-th capacitor electrode C2a and the 2-2-th capacitor electrode C2b with the first interlayer insulating layer 113 therebetween.

The second layer C2c2 of the 2-3-th capacitor electrode C2c may be disposed on the second interlayer insulating layer 114. The second layer C2c2 is a part extending from the source electrode SE of the driving transistor DT and may be connected to the first layer C2c1 through the contact hole of the second interlayer insulating layer 114.

Accordingly, the second capacitor C2 is electrically connected between the source electrode SE of the driving transistor DT and the light emitting element 130 to increase capacitance inherent in the light emitting element 130 and allow the light emitting element 130 to emit light with a higher luminance.

A first passivation layer 115a may be disposed on the driving transistor DT, the first capacitor C1, and the second capacitor C2. Here, the first passivation layer 115a is an insulating layer which protects components below the first passivation layer 115a and for example, may be configured by an inorganic material, such as silicon oxide SiOx or silicon nitride SiNx, but is not limited thereto.

A first planarization layer 116a may be disposed on the first passivation layer 115a. The first planarization layer 116a may planarize an upper portion of the pixel circuit including the driving transistor DT. The first planarization layer 116a may be configured by a single layer or a double layer, and for example, configured by benzocyclobutene or an acrylic organic material, but is not limited thereto.

A reflection plate RF may be disposed on the first planarization layer 116a. The reflection plate RF is a configuration which reflects light emitted from the plurality of light emitting elements 130 above the first substrate 110 and may be formed with a shape corresponding to each of the plurality of sub pixels SP. One reflection plate RF may be disposed to cover the most area of one sub pixel SP. The reflection plate RF may reflect the light emitted from the light emitting element 130 and may be also used as an electrode which electrically connects the light emitting element 130 and the pixel circuit. For example, the reflection plate RF may be electrically connected to the source electrode SE of the driving transistor DT and the second capacitor C2 through a first contact hole CH1 of the first planarization layer 116a and the first passivation layer 115a. The reflection plate RF may be electrically connected to the first electrode 134 of the light emitting element 130 through the second connection electrode CE2. Therefore, the reflection plate RF may electrically connect the driving transistor DT and the first electrode 134 of the light emitting element 130. The reflection plate RF may electrically connect the second electrode 135 of the light emitting element 130 and the high potential power line VL1, instead of connecting the first electrode 134 of the light emitting element 130 and the driving transistor DT, but is not limited thereto.

The reflection plate RF may include various conductive layers in consideration of a light reflection efficiency and a resistance. For example, the reflection plate RF may use an opaque conductive layer such as silver (Ag), aluminum (Al), molybdenum (Mo), titanium (Ti), or an alloy thereof and a transparent conductive layer such as indium tin oxide together, but the structure of the reflection plate RF is not limited thereto.

The second passivation layer 115b may be disposed on the reflection plate RF. At this time, the second passivation layer 115b is an insulating layer which protects components below the second passivation layer 115b and for example, may be configured by a single layer or a double layer of silicon oxide SiOx or silicon nitride SiNx, but is not limited thereto.

An adhesive layer AD may be disposed on the second passivation layer 115b. The adhesive layer AD is formed on the entire surface of the first substrate 110 to fix the light emitting element 130 disposed on the adhesive layer AD. The adhesive layer AD may be formed of a photo curable adhesive material which is cured by light. For example, the adhesive layer AD may be formed of an acrylic material including a photoresist, but is not limited thereto. The adhesive layer AD may be formed on the entire surface of the first substrate 110 excluding pad areas PA1 and PA2 in which the first pad electrode PAD1 is disposed.

The plurality of light emitting elements 130 may be disposed in each of the plurality of sub pixels SP on the adhesive layer AD. The light emitting element 130 is an element which emits light by a current and may include a red light emitting element 130 which emits red light, a green light emitting element 130 which emits green light, and a light emitting element 130 which emits blue light and may implement light with various colors including white by a combination thereof. For example, the light emitting element 130 may be a light emitting diode (LED) or a micro LED, but is not limited thereto.

For example, the plurality of light emitting elements 130 includes a first semiconductor layer 131, an emission layer 132, a second semiconductor layer 133, a first electrode 134, and a second electrode 135.

The first semiconductor layer 131 may be disposed on the adhesive layer AD and the second semiconductor layer 133 may be disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n type and p type impurities into a material such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium, tin (Sn), and the like, but are not limited thereto.

The emission layer 132 may be disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN), gallium nitride (GaN), or the like, but is not limited thereto.

The first electrode 134 may be disposed on the first semiconductor layer 131. The first electrode 134 is an electrode which electrically connects the driving transistor DT and the first semiconductor layer 131. The first semiconductor layer 131 is a semiconductor layer doped with an n-type impurity and the first electrode 134 may be a cathode. The first electrode 134 may be disposed on a top surface of the first semiconductor layer 131 which is exposed from the emission layer 132 and the second semiconductor layer 133. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 may be disposed on the second semiconductor layer 133. The second electrode 135 may be disposed on the top surface of the second semiconductor layer 133. The second electrode 135 is an electrode which electrically connects the high potential power line VL1 and the second semiconductor layer 133. In this case, the second semiconductor layer 133 is a semiconductor layer doped with a p-type impurity and the second electrode 135 may be an anode. The second electrode 135 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The encapsulation layer 136 which encloses the first semiconductor layer 131, the emission layer 132, the second semiconductor layer 133, the first electrode 134, and the second electrode 135 may be disposed. The encapsulation layer 136 is formed of an insulating material to protect the first semiconductor layer 131, the emission layer 132, and the second semiconductor layer 133. In the encapsulation layer 136, a contact hole which exposes the first electrode 134 and the second electrode 135 is formed to electrically connect a first connection electrode CE1 and a second connection electrode CE2 to the first electrode 134 and the second electrode 135.

In the meantime, a part of the side surface of the first semiconductor layer 131 may be exposed from the encapsulation layer 136. The light emitting element 130 manufactured on the wafer is separated from the wafer to be transferred onto the display panel PN. However, during the process of separating the light emitting element 130 from the wafer, a part of the encapsulation layer 136 may be torn. For example, a part of the encapsulation layer 136 which is adjacent to a lower edge of the first semiconductor layer 131 of the light emitting element 130 is torn during the process of separating the light emitting element 130 from the wafer. Accordingly, a part of a lower side surface of the first semiconductor layer 131 may be exposed to the outside. However, even though the lower portion of the light emitting element 130 is exposed from the encapsulation layer 136, the first connection electrode CE1 and the second connection electrode CE2 are formed after forming the second planarization layer 116b and the third planarization layer 116c which cover the side surface of the first semiconductor layer 131. Accordingly, a short problem may be reduced.

Next, the second planarization layer 116b and the third planarization layer 116c may be disposed on the adhesive layer AD and the light emitting element 130.

The second planarization layer 116b overlaps a part of side surfaces of the plurality of light emitting elements 130 to fix and protect the plurality of light emitting elements 130. The second planarization layer 116b may be formed using a halftone mask. Therefore, the second planarization layer 116b may be formed to have a step.

For example, a part of the second planarization layer 116b which is relatively adjacent to the light emitting element 130 may be formed to have a smaller thickness and a part which is farther from the light emitting element 130 may be formed to have a larger thickness. A part of the second planarization layer 116b which is adjacent to the light emitting element 130 may be disposed to enclose the light emitting element 130 and also may be in contact with a side surface of the light emitting element 130. Therefore, a torn part of the encapsulation layer 136 which protects a side surface of the first semiconductor layer 131 of the light emitting element 130 during the process of separating the light emitting element 130 from the wafer to be transferred onto the display panel PN may be covered by the second planarization layer 116b. By doing this, contacts and short problems of the connection electrodes CE1 and CE2 and the first semiconductor layer 131 later may be suppressed.

The third planarization layer 116c is formed to cover upper portions of the second planarization layer 116b and the light emitting element 130 and a contact hole which exposes the first electrode 134 and the second electrode 135 of the light emitting element 130 may be formed. The first electrode 134 and the second electrode 135 of the light emitting element 130 are exposed from the third planarization layer 116c and the third planarization layer 116c is partially disposed in an area between the first electrode 134 and the second electrode 135 to reduce a short problem. The second planarization layer 116b and the third planarization layer 116c may be configured by a single layer or a double layer, and for example, may be formed of a photoresist or an acrylic organic material, but is not limited thereto.

In the meantime, the third planarization layer 116c may cover only the light emitting element 130 and an area adjacent to the light emitting element 130. For example, the third planarization layer 116c may be disposed in an area of the sub pixel SP enclosed by the bank BB and may be disposed in an island shape. A bank BB may be disposed in a part of the top surface of the second planarization layer 116b and the third planarization layer 116c may be disposed in the other part of the top surface of the second planarization layer 116b.

The first connection electrode CE1 and the second connection electrode CE2 may be disposed on the third planarization layer 116c. The first connection electrode CE1 is an electrode which electrically connects the second electrode 135 of the light emitting element 130 and the high potential power line VL1. The first connection electrode CE1 may be electrically connected to the second electrode 135 of the light emitting element 130 through a contact hole formed in the third planarization layer 116c.

Further, the second connection electrode CE2 is an electrode which electrically connects the first electrode 134 of the light emitting element 130 and the driving transistor DT. The second connection electrode CE2 may be connected to the reflection plate RF of each of the plurality of sub pixels SP through contact holes formed in the third planarization layer 116c, the second planarization layer 116b, the adhesive layer AD, and the second passivation layer 115b. The reflection plate RF is also connected to the source electrode SE of the driving transistor DT so that the source electrode SE of the driving transistor DT and the first electrode 134 of the light emitting element 130 may be electrically connected to each other.

A bank BB may be disposed on the first connection electrode CE1, the second connection electrode CE2, and the second planarization layer 116b exposed from the third planarization layer 116c. The bank BB may be disposed to be spaced apart from the light emitting element 130 with a predetermined interval and overlap at least partially the reflection plate RF. For example, the bank BB may cover a part of the second connection electrode CE2 formed in the contact holes of the third planarization layer 116c and the second planarization layer 116b. Further, the bank BB may be disposed on the second planarization layer 116b with a predetermined interval from the light emitting element 130. In this case, the bank BB and the third planarization layer 116c may be spaced apart from each other on a part of the second planarization layer 116b having a smaller thickness. That is, an end of the bank BB and an end of the third planarization layer 116c may be disposed on a part of the second planarization layer 116b having a smaller thickness formed by a halftone mask process to be spaced apart from each other.

The bank BB may be formed of an opaque material to reduce color mixture between the plurality of sub pixels SP and for example, may be formed of black resin, but is not limited thereto.

In the meantime, a thickness of a part of the bank BB which is formed in the contact holes of the third planarization layer 116c and the second planarization layer 116b to cover a part of the second connection electrode CE2 and a thickness of a part disposed on the second planarization layer 116b may be different from each other. For example, when the part of the bank BB covers a part of the second connection electrode CE2 formed in the contact holes of the third planarization layer 116c and the second planarization layer 116b, since the contact hole is formed from the second passivation layer 115b to the third planarization layer 116c, the bank BB may be disposed below the light emitting element 130, that is, disposed to be lower than the light emitting element 130. Therefore, the thickness of the part of the bank BB which covers a part of the second connection electrode CE2 formed in the contact holes of the third planarization layer 116c and the second planarization layer 116b may be larger than the thickness of a part of the bank BB disposed on the second planarization layer 116b.

Next, a first protection layer 117 may be disposed on the first connection electrode CE1, the second connection electrode CE2, and the bank BB. The first protection layer 117 is a layer for protecting components below the first protection layer 117, and may be configured by a single layer or a double layer of translucent epoxy, silicon oxide SiOx or silicon nitride SiNx, but is not limited thereto.

A plurality of first pad electrodes PAD1 may be disposed in a first pad area PA1 and a second pad area PA2 of the first substrate 110. Each of the plurality of first pad electrodes PAD1 may be configured by a plurality of conductive layers. For example, each of the plurality of first pad electrodes PAD1 may include a first conductive layer PE1a, a second conductive layer PE1b, and a third conductive layer PE1c.

First, the first conductive layer PE1a may be disposed on the second interlayer insulating layer 114. The first conductive layer PE1a may be formed of the same conductive material as the source electrode SE and the drain electrode DE and for example, may be configured by copper (Cu), aluminum (Al), molybdenum (Mo), nickel (Ni), titanium (Ti), chrome (Cr), or an alloy thereof, but is not limited thereto.

The first passivation layer 115a may be disposed on the first conductive layer PE1a and the second conductive layer PE1b may be disposed on the first passivation layer 115a.

The second conductive layer PE1b may be formed of the same conductive material as the reflection plate RF and for example, may be configured by silver (Ag), aluminum (Al), molybdenum (Mo), or an alloy thereof, but is not limited thereto.

The third conductive layer PE1c may be disposed on the second conductive layer PE1b.

The third conductive layer PE1c may be formed of the same conductive material as the first connection electrode CE1 and the second connection electrode CE2, and for example, a transparent conductive material, such as indium tin oxide (ITO) or indium zinc oxide (IZO), but is not limited thereto.

At this time, even though it is not illustrated in the drawings, some of the plurality of conductive layers of the first pad electrode PAD1 are electrically connected to a plurality of wiring lines on the first substrate 110 to supply various signals to a plurality of wiring lines and a plurality of sub pixels SP. For example, the first conductive layer PE1a and/or the second conductive layer PE1b of the first pad electrode PAD1 is connected to the data line DL, the high potential power line VL1, and the low potential power line VL2 disposed in the active area AA to transmit signals thereto.

A first metal layer ML1, a second metal layer ML2, and a plurality of insulating layers may be disposed together below the first pad electrode PAD1. The first metal layer ML1, the second metal layer ML2, and the plurality of insulating layers are disposed below the first pad electrode PAD1 to adjust a step of the first pad electrode PAD1. For example, the buffer layer 111, the gate insulating layer 112, the first metal layer ML1, the first interlayer insulating layer 113, and the second metal layer ML2 may be sequentially disposed between the first pad electrode PAD1 and the first substrate 110. For example, the first metal layer ML1 may be formed of the same conductive material as the gate electrode GE and the second metal layer ML2 may be formed of the same conductive material as a 1-2-th capacitor electrode C1b. However, the plurality of insulating layers, the first metal layer, and the second metal layer below the first pad electrode PAD1 may be omitted depending on a design and are not limited thereto.

A second substrate 120 may be disposed below the first substrate 110. The second substrate 120 is a substrate which supports components disposed below the display device 100 and may be an insulating substrate. For example, the second substrate 120 may be formed of glass, resin, or the like. Further, the second substrate 120 may include polymer or plastic. The second substrate 120 may be formed of the same material as the first substrate 110. In some exemplary embodiments, the second substrate 120 may be formed of a plastic material having flexibility.

A bonding layer BDL may be disposed between the first substrate 110 and the second substrate 120. For example, the bonding layer BDL may be formed of a material which is cured by various curing methods to bond the first substrate 110 and the second substrate 120. The bonding layer BDL may be disposed only in a partial area between the first substrate 110 and the second substrate 120 or may be disposed in the entire area.

A plurality of second pad electrodes PAD2 may be disposed on a rear surface of the second substrate 120. The plurality of second pad electrodes PAD2 is electrodes which transmit a signal from a driving component disposed on the rear surface of the second substrate 120 to a plurality of side lines SRL and a plurality of first pad electrodes PAD1 and a plurality of wiring lines on the first substrate 110. For example, the plurality of second pad electrodes PAD2 is disposed in an end portion of the second substrate 120 in the non-active area NA to be electrically connected to the side line SRL which covers the end portion of the second substrate 120.

At this time, the plurality of second pad electrodes PAD2 may be also disposed so as to correspond to the plurality of pad areas PA1 and PA2. The plurality of first pad electrodes PAD1 may be disposed to correspond to the plurality of second pad electrodes PAD2, respectively, and then the first pad electrode PAD1 and the second pad electrode PAD2 which overlap each other may be electrically connected through the side line SRL.

Each of the plurality of second pad electrodes PAD2 may include a plurality of conductive layers.

For example, each of the plurality of second pad electrodes PAD2 may include a fourth conductive layer PE2a, a fifth conductive layer PE2b, and a sixth conductive layer PE2c.

First, the fourth conductive layer PE2a may be disposed below the second substrate 120. The fourth conductive layer PE2a may be configured by a conductive material such as copper (Cu), aluminum (Al), molybdenum (Mo), nickel (Ni), titanium (Ti), chrome (Cr), or an alloy thereof, but is not limited thereto.

The fifth conductive layer PE2b may be disposed below the fourth conductive layer PE2a. The fifth conductive layer PE2b may be configured by a conductive material, such as copper (Cu), aluminum (Al), molybdenum (Mo), nickel (Ni), titanium (Ti), chrome (Cr), or an alloy thereof, but is not limited thereto.

The sixth conductive layer PE2c may be disposed below the fifth conductive layer PE2b. The sixth conductive layer PE2c may be formed of a conductive material, for example, a transparent conductive material, such as indium tin oxide (ITO) or indium zinc oxide (IZO), but is not limited thereto.

The second protection layer 121 may be disposed in the remaining area of the second substrate 120. The second protection layer 121 may protect various wiring lines and driving components formed on the second substrate 120. The second protection layer 121 may be configured by an organic insulating material, and for example, configured by benzocyclobutene or an acrylic organic insulating material, but is not limited thereto.

Even though it is not illustrated in the drawing, a driving component including a plurality of flexible films and a printed circuit board may be disposed on a rear surface of the second substrate 120. The plurality of flexible films is components in which various components such as a data driver IC are disposed on a base film having a ductility to supply signals to the plurality of sub pixels SP. The printed circuit board is a component which is electrically connected to the plurality of flexible films to supply signals to the driving IC. On the printed circuit board, various components for supplying various signals to the driving IC may be disposed.

For example, the fourth conductive layer PE2a and/or the fifth conductive layer PE2b of the second pad electrode PAD2 extend to the plurality of flexible films disposed on the rear surface of the second substrate 120 to be electrically connected to the plurality of flexible films. The plurality of flexible films may supply various signals to the plurality of side lines SRL, the plurality of first pad electrodes PAD1, the plurality of wiring lines, and the plurality of sub pixels SP through the second pad electrode PAD2. Therefore, the signal from the driving component may be transmitted to the signal line and the plurality of sub pixels SP on the front surface of the first substrate 110 through the plurality of second pad electrodes PAD2 of the second substrate 120, the side line SRL, and the plurality of first pad electrodes PAD1 of the first substrate 110.

Next, the plurality of side lines SRL may be disposed on the side surfaces of the first substrate 110 and the second substrate 120. The plurality of side lines SRL may electrically connect the plurality of first pad electrodes PAD1 formed on the top surface of the first substrate 110 and the plurality of second pad electrodes PAD2 formed on the rear surface of the second substrate 120. The plurality of side lines SRL may be disposed so as to enclose the side surface of the display device 100. Each of the plurality of side lines SRL may cover the first pad electrode PAD1 at an end portion of the first substrate 110, a side surface of the first substrate 110, a side surface of the second substrate 120, and the second pad electrode PAD2 at an end portion of the second substrate 120. For example, the plurality of side lines SRL may be formed by a pad printing method using a conductive ink, for example, including silver (Ag), copper (Cu), molybdenum (Mo), chrome (Cr), and the like.

A side insulating layer 140 which covers the plurality of side lines SRL may be disposed. The side insulating layer 140 may be formed on the top surface of the first substrate 110, the side surface of the first substrate 110, the side surface of the second substrate 120, and the rear surface of the second substrate 120 to cover the side line SRL. The side insulating layer 140 may protect the plurality of side lines SRL.

When the plurality of side lines SRL is formed of a metal material, there may be a problem in that external light is reflected from the plurality of side lines SRL or light emitted from the light emitting element 130 is reflected from the plurality of side lines SRL to be visibly recognized by the user. Therefore, the side insulating layer 140 is configured to include a black material to suppress reflection of the external light. For example, the side insulating layer 140 may be formed by a pad printing method using an insulating material including a black material, for example, a black ink.

A seal member 150 which covers the side insulating layer 140 may be disposed.

The seal member 150 is disposed so as to enclose the side surface of the display device 100 to protect the display device 100 from external impacts, moisture, and oxygen. For example, the seal member 150 may be formed of polyimide (PI), poly urethane, epoxy, or acryl based insulating material, but is not limited thereto.

An optical film MF may be disposed on the seal member 150, the side insulating layer 140, and the first protection layer 117. The optical film MF may be a functional film which implements a higher quality of images while protecting the display device 100. For example, the optical film MF may include an anti-scattering film, an anti-glare film, an anti-reflecting film, a low-reflecting film, a transmittance controllable film, a polarizer, or the like, but is not limited thereto.

An edge of the seal member 150 and an edge of the optical film MF may be disposed on the same line. The optical film MF having a larger size is attached above the first substrate 110 during the manufacturing process of the display device 100 and the seal member 150 which covers the side insulating layer 140 may be formed. Thereafter, laser is irradiated on the seal member 150 and the optical film MF so as to correspond to an edge of the display device 100 to cut a part of the seal member 150 and the optical film MF. Accordingly, the size of the display device 100 may be adjusted by an outer periphery cutting process of the seal member 150 and the optical film MF and the edge of the display device 100 may be formed to be flat.

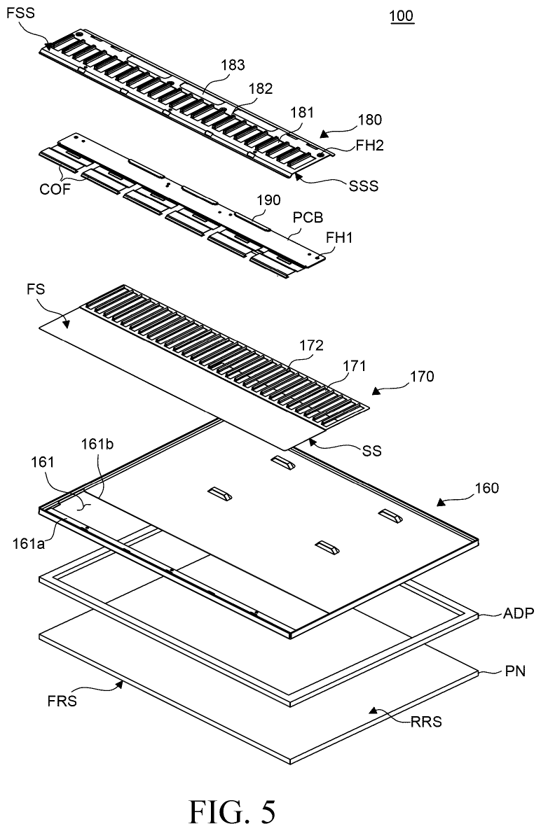

Hereinafter, a mechanical structure of the display device 100 according to the exemplary embodiment of the present disclosure will be described with reference to FIGS. 5 to 8.

FIG. 5 is an exploded perspective view of a display device according to an exemplary embodiment of the present disclosure.

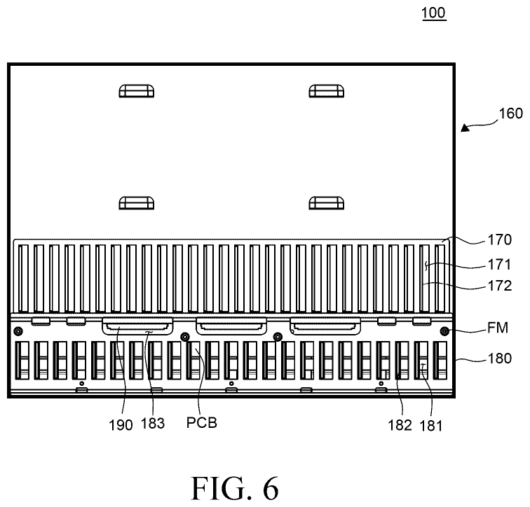

FIG. 6 is a rear view of a display device according to an exemplary embodiment of the present disclosure.

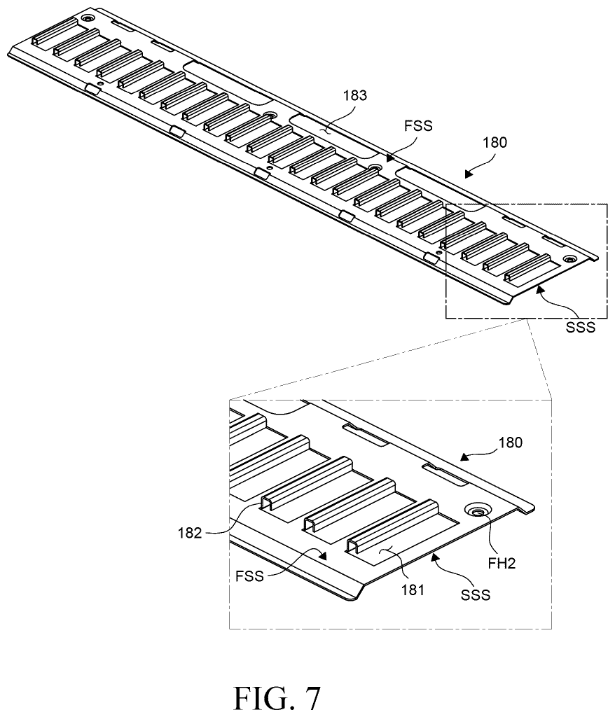

FIG. 7 is an enlarged perspective view of a cover shield of FIG. 6.

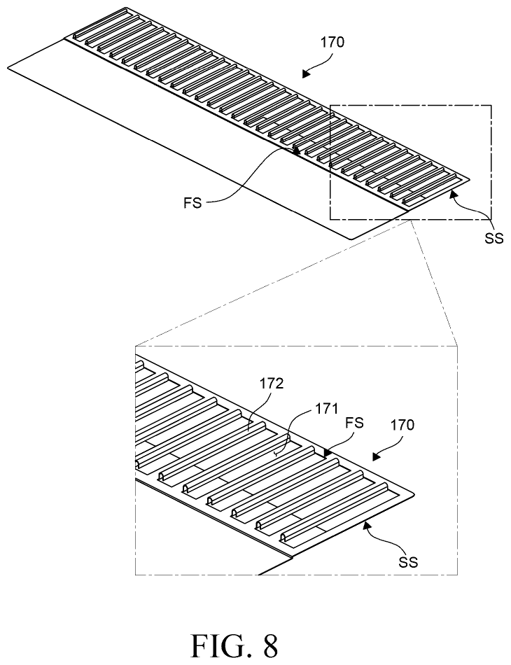

FIG. 8 is an enlarged perspective view of a plate bottom of FIG. 6.

A surface directed to a lower side in FIG. 5 corresponds to a front surface FRS of the display panel PN on which an image is displayed and a surface directed to an upper side corresponds to a rear surface RRS of the display panel PN.

Referring to FIGS. 5 to 8, the display device 100 of the exemplary embodiment of the present disclosure may include a display panel PN, an adhesive member ADP, a cover bottom 160, a plate bottom 170, a printed circuit board PCB, and a cover shield 180.

A plurality of flexible films COF may be bonded onto a rear surface RRS of the display panel PN. The plurality of flexible films COF may be electrically connected to the plurality of second pad electrodes (PAD2 of FIG. 4) of the second substrate (120 of FIG. 4) of the display panel PN.

The flexible film COF is a film in which various components are disposed on a base film having a ductility to supply a signal to the sub pixel SP and a driving component and may be connected to the display panel PN.

A driving IC such as a gate driver IC or a data driver IC may be disposed on the plurality of flexible films COF. The driving IC is a component which processes data for displaying images and a driving signal for processing the data. The driving IC may be disposed in a chip on glass (COG), a chip on film (COF), or a tape carrier package (TCP) manner depending on a mounting method. However, for the convenience of description, it is described that the driving IC is mounted on the flexible film COF by a chip on film technique, but is not limited thereto.

The printed circuit board PCB may be electrically connected to the plurality of flexible films COF. The printed circuit board PCB is a component which supplies signals to the driving IC. On the printed circuit board PCB, various components for supplying various signals to the driving IC may be disposed.

In the meantime, even though in FIG. 5, it is illustrated that six flexible films COF and one printed circuit board PCB are provided, the number of flexible films COF and printed circuit boards PCB may vary depending on a design.

The printed circuit board PCB may include a first fastening hole FH1. For example, a fastening member FM is inserted into the first fastening hole FH1 formed in the printed circuit board PCB so that the printed circuit board PCB and the plate bottom 170 and the cover shield 180 may be fastened with each other.

A cover bottom 160 may be disposed on a rear surface of the display panel PN.

The cover bottom 160 may support and protect the display panel PN from the rear surface of the display panel PN. For example, the cover bottom 160 is formed to have a shape corresponding to a planar shape of the display panel PN to cover the display panel PN. The cover bottom 160 may be formed of a material having a rigidity and a high thermal conductivity and for example, may be formed of a metal material such as iron (Fe), copper (Cu), aluminum (Al), zinc (Zn), silver (Ag), gold (Au), steel use stainless (SUS), or invar, or a plastic material.

The cover bottom 160 may include an opening 161.

The opening 161 of the cover bottom 160 may be disposed so as to correspond to the plurality of flexible films COF and the printed circuit board PCB. For example, the opening 161 of the cover bottom 160 may overlap with the printed circuit board PCB from a plan view as shown in FIG. 5. The opening 161 may be located on an area of the display panel PN to which the plurality of flexible films COF is bonded. For example, the plurality of flexible films COF is bonded to an area adjacent to one edge of the display panel PN and the opening 161 may be also formed so as to correspond to an area adjacent to one edge of the display panel PN.

For example, the plurality of flexible films COF and the printed circuit board PCB pass through the opening 161 to be disposed on the rear surface of the cover bottom 160. Therefore, the plurality of flexible films COF and the printed circuit board PCB may be disposed on the rear surface of the cover bottom 160 without preparing a separate area for disposing the plurality of flexible films COF and the printed circuit board PCB between the cover bottom 160 and the display panel PN. The plate bottom 170 is seated in the opening 161 of the cover bottom 160 to support the printed circuit board PCB, which will be described in more detail below.

A protrusion 161a may be disposed at the edge of the opening, but is not limited thereto.

The protrusion 161a may be disposed at one edge adjacent to one edge of the display panel PN, among edges of the opening 161. For example, the protrusion 161a may be disposed at one edge the most adjacent to a lower edge of the display panel PN, among edges of the opening 161. The protrusion 161a may protrude toward a direction perpendicular to the rear surface of the cover bottom 160 from one edge of the opening 161. The protrusion 161a is engaged with the cover shield 180 to restrict the movement of the cover shield 180 and guide a position of the cover shield 180.

Even though it is not illustrated in the drawings, a plurality of second openings may be further disposed along an edge of the cover bottom 160. The plurality of second openings may be disposed to be parallel to the edge of the cover bottom 160. The plurality of second openings are openings cut while forming the plurality of second protrusions. In this case, the above-described opening 161 and protrusion 161a may be referred to as a first opening and a first protrusion, respectively.

For example, the plurality of second protrusions is parts which couple the display device 100 to a cabinet. The plurality of second protrusions is used to fix the display device 100 to the cabinet in the form of a tile to form a tiling display device (TD in FIG. 2B). The plurality of second protrusions is formed by bending a part of the cover bottom 160 in a direction perpendicular to the rear surface of the cover bottom 160 and may have an L-shaped cross-sectional shape.

The second protrusion may be formed by cutting and bending a part of the cover bottom 160. Therefore, when the plurality of second protrusions is formed, the plurality of second openings may be formed in a part in which the cover bottom 160 is cut. Therefore, the second protrusion may be disposed on the edges of the plurality of second openings. For example, the second protrusion may be disposed on an edge parallel to the edge of the cover bottom 160, among the edges of the second openings.

Next, the plate bottom 170 may be disposed between the printed circuit board PCB and the opening 161 of the cover bottom 160. For example, a part of the plate bottom 170 may cover the other edge of the opening 161 and the cover bottom 160 and the other part of the plate bottom 170 may be disposed in the opening 161. The plate bottom 170 passes through the opening 161 to support the printed circuit board PCB disposed on the cover bottom 160.

The plate bottom 170 may disperse and dissipate the heat generated in the printed circuit board PCB. The plate bottom 170 does not allow the printed circuit board PCB to be in direct contact with the display panel PN to reduce or minimize the concentration of the heat of the printed circuit board PCB on a specific area of the display panel PN. In the meantime, the printed circuit board PCB includes a plurality of components and among the components, an IC chip 190 which generates a lot of heat may be disposed and this part may form a heat generating unit.

Various IC chips are provided in the printed circuit board PCB, and among them, there is an IC chip 190 which generates a lot of heat. For example, a power management IC (PMIC) generates various power voltages so that the PMIC generates a lot of heat and specifically, an IC FET or a buck IC which generates VDD generates a lot of heat, but is not limited thereto. Two FETs and the buck IC are included in the PMIC and may be used to generate various voltages such as VDD, VSS, and Vref. The plate bottom 170 disperses the heat generated in the IC chip 190 of the printed circuit board PCB which generates a lot of heat to the entire plate bottom 170 so as not to concentrate the heat on a partial area of the display panel PN adjacent to the IC chip 190 which generates a lot of heat and may reduce the entire temperature deviation of the display panel PN.

Even though it is not illustrated, the plate bottom 170 may include a fastening unit.

The fastening unit is a part to which the fastening member FM which passes through the first fastening hole FH1 of the printed circuit board PCB and the second fastening hole FH2 of the cover shield 180 is coupled. For example, the fastening member FM is coupled to the fastening unit to fix the plate bottom 170, the printed circuit board PCB, and the cover shield 180 to each other. For example, the fastening unit may be a Pem-nut having a groove with a thread of a screw therein, but is not limited thereto.

In the meantime, a plurality of first vent holes 171 and a plurality of first heat dissipation fins 172 for heat dissipation may be provided in the other edge of the opening 161 of the cover bottom 160 and a part of the plate bottom 170 which covers the cover bottom 160.

The plurality of first vent holes 171 and the plurality of first heat dissipation fins 172 are exposed without being covered by the cover shield 180 to discharge heat of the printed circuit board PCB, specifically, the IC chip 190 which generates a lot of heat, to the outside.

For example, the plurality of first vent holes 171 may be disposed along the edge of the plate bottom 170. Further, the plurality of first vent holes 171 may be disposed along the edge of the plate bottom 170 to be perpendicular to the edge of the plate bottom 170. In FIGS. 5 and 8, it is illustrated that the plurality of first vent holes 171 is disposed to be perpendicular to an edge of the plate bottom 170, that is, the other edge of the opening 161. However, the present disclosure is not limited thereto so that the plurality of first vent holes 171 may be disposed to be parallel to the other edge of the opening 161.

For example, the plurality of first vent holes 171 may be configured by an opening cut while forming the plurality of first heat dissipation fins 172. The first heat dissipation fin 172 may be formed by cutting and bending a part of the plate bottom 170. Therefore, when the plurality of first heat dissipation fins 172 is formed, the plurality of first vent holes 171 may be formed in a part in which the plate bottom 170 is cut. Therefore, the first heat dissipation fin 172 may be disposed on the edge of the first vent hole 171. For example, the first heat dissipation fin 172 may be disposed on the edge which is perpendicular to the edge of the plate bottom 170, among edges of the first vent holes 171. As described above, the plate bottom 170 of the present disclosure including the plurality of first vent holes 171 and first heat dissipation fins 172 may perform both functions of protecting the printed circuit board PCB and effectively discharging the heat of the heat generating unit. Further, there is an advantage in that the plurality of first vent holes 171 and first heat dissipation fins 172 are simultaneously formed only by a press process on the plate bottom 170. In one or more embodiments, the printed circuit board PCB overlaps with the plate bottom 170 from a plan view.

At this time, the plurality of first vent holes 171 may serve to induce heat dissipation convection and the plurality of first heat dissipation fins 172 may function to increase a heat dissipation efficiency by increasing a surface area for convecting air. That is, the plurality of first heat dissipation fins 172 may increase a surface area exposed to the air to increase the heat dissipation effect.

Even though in FIGS. 5 and 8, it is illustrated that the first heat dissipation fin 172 is bent in a U shape toward the inside of the first vent hole 171, the present disclosure is not limited thereto and the first heat dissipation fin 172 may also be bent in a U shape toward the outside of the first vent hole 171.

The first heat dissipation fin 172 may be disposed at one edge among edges of the first vent holes 171. For example, the first heat dissipation fin 172 is a part of one edge of the first vent hole 171 which is bent toward the inside of the first vent hole 171 and may have a “U” shaped cross-section.

Next, a cover shield 180 may be disposed on the cover bottom 160, the plate bottom 170, and the printed circuit board PCB. The cover shield 180 may protect the printed circuit board PCB from the external impact. The cover shield 180 is formed of a material having a rigidity to protect the printed circuit board PCB, but is not limited thereto.

The cover shield 180 may be disposed on the rear surface of the cover bottom 160 to cover the printed circuit board PCB. One edge of the cover shield 180 is bent in an L-shape and may be in contact with an outer side surface of the protrusion 161a of the cover bottom 160. Therefore, the protrusion 161a and one side portion of the cover shield 180 are engaged with each other to restrict the movement of the cover shield 180 and guide the position of the cover shield 180.

The cover shield 180 may include a plurality of second vent holes 181. For example, the plurality of second vent holes 181 may be disposed in the most area of the cover shield 180. The plurality of second vent holes 181 is formed to dissipate the heat generated in the printed circuit board PCB to the outside of the cover shield 180. The IC chip 190 which generates a lot of heat, among the plurality of components of the printed circuit board PCB, may be exposed from the cover shield 180 through a third opening 183. For example, the IC chip 190 which generates a lot of heat is exposed from the cover shield 180 through the third opening 183 to efficiently discharge heat generated in the IC chip 190 which generates a lot of heat. Therefore, the third opening 183 may be formed in a part of the cover shield 180 according to the position of the IC chip 190 which generates a lot of heat. For example, the third opening 183 of the cover shield 180 is configured to overlap with the printed circuit board where an integrated circuit chip 190 is located from a plan view. Even though in FIGS. 5 and 7, it is illustrated that three third openings 183 are formed in an upper side of the cover shield 180, the position and the number of third openings are not limited thereto.

The cover shield 180 may include a plurality of second heat dissipation fins 182.

As the same as described above, for example, the plurality of second vent holes 181 may be configured by an opening cut while forming the plurality of second heat dissipation fins 182. The second heat dissipation fin 182 may be formed by cutting and bending a part of the cover shield 180. Therefore, when the plurality of second heat dissipation fins 182 is formed, the plurality of second vent holes 181 may be formed in a part in which the cover shield 180 is cut. Therefore, the second heat dissipation fin 182 may be disposed on the edge of the second vent hole 181. For example, the second heat dissipation fin 182 may be disposed on the edge which is perpendicular to the edge of the cover shield 180, among edges of the second vent holes 181. As described above, the cover shield 180 of the present disclosure including the plurality of second vent holes 181 and the plurality of second heat dissipation fins 182 may perform both functions of protecting the printed circuit board PCB and effectively discharging the heat of the heat generating unit. Further, there is an advantage in that the plurality of second vent holes 181 and the plurality of second heat dissipation fins 182 are simultaneously formed only by a press process on the cover shield 180.

As the same as described above, the plurality of second vent holes 181 may serve to induce heat dissipation convection and the plurality of second heat dissipation fins 182 may function to increase a heat dissipation efficiency by increasing a surface area for convecting air. The plurality of second heat dissipation fins 182 may increase a surface area exposed to the air to increase the heat dissipation effect. In some embodiments, the cover shield 180 may overlap with the printed circuit board PCB from a plan view such that the plurality of second vent holes 181 exposes at least a portion of the printed circuit board PCB.

Even though in FIGS. 5 and 7, it is illustrated that the second heat dissipation fin 182 is bent in a U shape toward the inside of the second vent hole 181, the present disclosure is not limited thereto and the second heat dissipation fin 182 may also be bent in a U shape toward the outside of the second vent hole 181. Further, the second heat dissipation fin 182 may have a U shape where the first heat dissipation fin 172 has a reversed U shape opposite of the shape of the second heat dissipation fin 182. That is, while FIG. 5, for example, illustrates the first and second heat dissipation fins 172, 182 to have the same shape in the same direction, the embodiments are not limited there to and may each have different shapes in different directions. Moreover, the number second vent holes 181 may have the same number as the first vent holes 171. However, in other embodiments, the number of second vent holes 181 and the number of first vent holes 171 may be different from each other. The distance between adjacent vent holes may also vary. That is, while the distances between adjacent vent holes have been illustrated as being identical to each other, the embodiments are not limited there to and each distance between adjacent vent holes may have varying length.

The second heat dissipation fin 182 may be disposed at one edge among edges of the second vent holes 181. That is, for example, the second heat dissipation fin 182 is a part of one edge of the second vent hole 181 which is bent toward the inside of the second vent hole 181 and may have a “U” shaped cross-section.

The cover shield 180 may include a plurality of second fastening holes FH2. A fastening member FM is inserted into the second fastening hole FH2 to fix the cover shield 180 to the printed circuit board PCB and the plate bottom 170. Specifically, the cover shield 180 and the printed circuit board PCB may be fixed to the plate bottom 170 by coupling the fastening member FM which passes through both the second fastening hole FH2 of the cover shield 180 and the first fastening hole FH1 of the printed circuit board PCB to the fastening unit of the plate bottom 170. The fastening member FM may be a bolt which is screwed to the fastening unit which is a nut, but is not limited thereto.

An adhesive member ADP may be disposed between the cover bottom 160 and the display panel PN. For example, the adhesive member ADP may be formed of a material with adhesiveness to fix the cover bottom 160 onto the rear surface of the display panel PN. The adhesive member ADP may be disposed along an edge of the display panel PN and an edge of the cover bottom 160. The adhesive member ADP may be formed in a frame shape corresponding to an edge of the display panel PN. For example, the adhesive member ADP may be a foam tape having adhesiveness, but is not limited thereto.

Referring to the enlarged view of FIG. 7, the cover shield 180 has a first surface FSS and a second surface SSS opposite the first surface FSS. Each second vent hole of the plurality of second vent holes 181 extends through the cover shield 180 from the first surface FSS to the second surface SSS. Each second heat dissipation fin of the plurality of second heat dissipation fins 182 extends in a direction opposite of the second surface SSS of the cover shield 180. Namely, the second heat dissipation fin protrudes upwards as shown in FIG. 7. The second heat dissipation fin may have a first portion, a second portion, and a third portion between the first and second portions. In one embodiment, as shown in FIG. 7, the first portion of the second heat dissipation fin may protrude upwards in a perpendicular direction (or vertical direction) from the first surface FSS. The third portion which extends from the first portion of the second heat dissipation fin may extend in a parallel direction (or a horizontal direction) with respect to the first surface FSS. The second portion which extends from the third portion of the second heat dissipation fin may extend towards the first surface FSS. The first, second, and third portions of the second heat dissipation fin may therefore, have a reversed U-shape or a hook shape.

Similarly, referring to the enlarged view of FIG. 8, the plate bottom 170 has a first surface FS and a second surface SS opposite the first surface FS. Each first vent hole of the plurality of first vent holes 171 extends through the plate bottom 170 from the first surface FS to the second surface SS. Each first heat dissipation fin of the plurality of first heat dissipation fins 172 extends in a direction opposite of the second surface SS of the plate bottom 170. Namely, the first heat dissipation fin protrudes upwards as shown in FIG. 8. The first heat dissipation fin may have a first portion, a second portion, and a third portion between the first and second portions. In one embodiment, as shown in FIG. 8, the first portion of the first heat dissipation fin may protrude upwards in a perpendicular direction (or vertical direction) from the first surface FS. The third portion which extends from the first portion of the first heat dissipation fin may extend in a parallel direction (or a horizontal direction) with respect to the first surface FS. The second portion which extends from the third portion of the first heat dissipation fin may extend towards the first surface FS. The first, second, and third portions of the first heat dissipation fin may therefore, have a reversed U-shape or a hook shape. In some embodiments, the shape of the first heat dissipation fin and the shape of the second heat dissipation fin may be the same. However, in other embodiments, the shape of the first heat dissipation fin and the shape of the second heat dissipation fin may be different from each other.

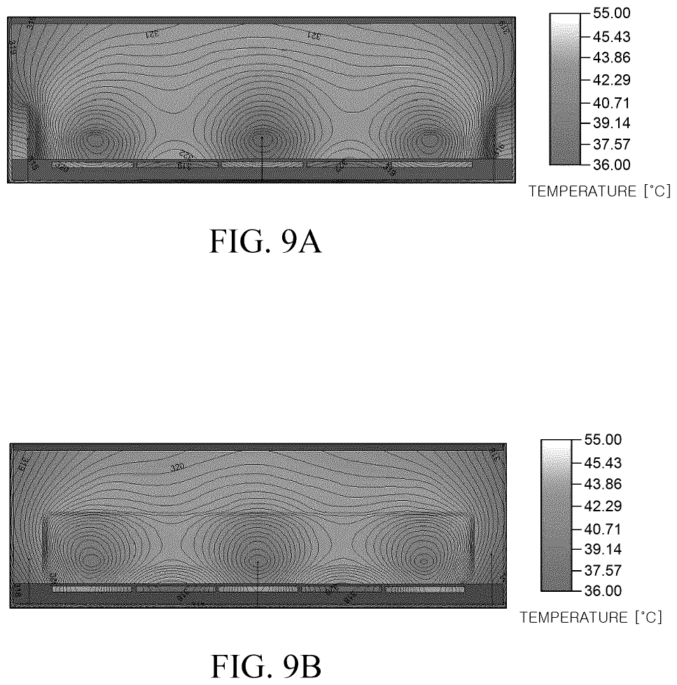

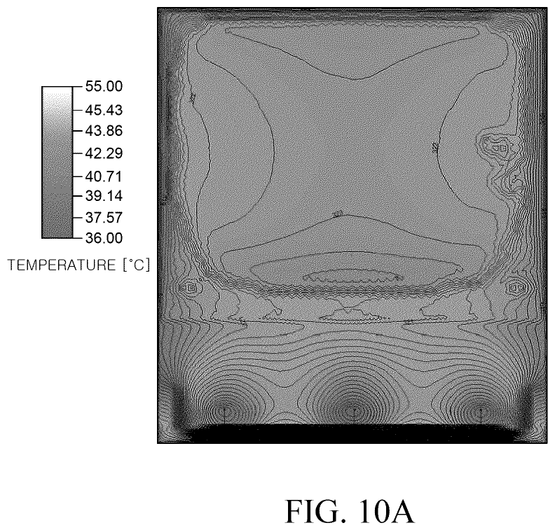

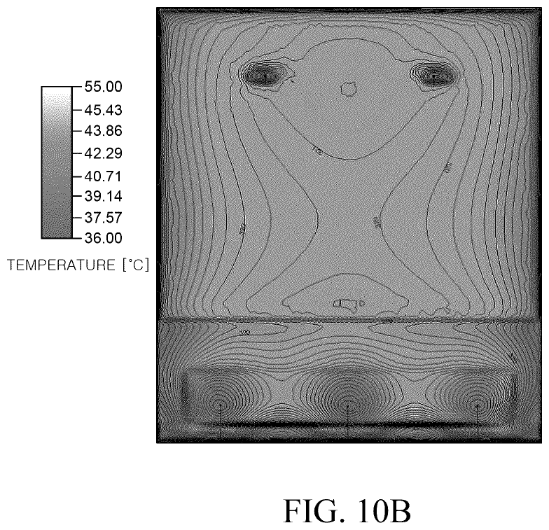

Hereinafter, an effect of decreasing a temperature of a display panel by a vent hole and a heat dissipation fin will be described with reference to FIGS. 9A, 9B, 10A, and 10B.

FIG. 9A is a simulation result of a temperature distribution of a heat generating unit according to a comparative embodiment.

FIG. 9B is a simulation result of a temperature distribution of a heat generating unit according to an exemplary embodiment.

FIG. 10A is a simulation result of a temperature of a front surface of a display device according to a comparative embodiment.

FIG. 10B is a simulation result of a temperature of a front surface of a display device according to an exemplary embodiment.

The display device according to the comparative embodiment has the same structure as the display device according to the exemplary embodiment of the present disclosure except that a heat dissipation fin is further included in addition to the vent hole in the display device according to the exemplary embodiment of the present disclosure.

FIGS. 9A and 9B illustrate a simulation result of a temperature distribution at a lower end of the display panel in which the printed circuit board including a heat generating unit is disposed. FIGS. 10A and 10B illustrate a simulation result of a temperature distribution on the front surface of the display panel.

Referring to FIGS. 9A and 10A, in the display device according to the comparative embodiment, it is understood that the maximum temperature is approximately 52.4° C.

In contrast, referring to FIGS. 9B and 10B, in the display device according to the exemplary embodiment, it is understood that the maximum temperature is approximately 49.3° C.

In the legend for FIGS. 9A, 9B, 10A and 10B, the gray scale for the temperatures is shown as ranging from 36° C. to 47° C., with the 36° C. being the darkest illustrated on the legend and 47° C. being the lightest, nearly white. For temperatures below 36° C. the graph will become slightly darker, until the darkest possible color is shown for that gray scale and as temperatures go above 47° C., the color shown will become lighter, becoming completely white at some temperature.

As described above, the display device according to the exemplary embodiment includes a vent hole and a heat dissipation fin for heat dissipation so that as compared with the display device of the comparative embodiment, the maximum temperature of the front surface of the display panel is reduced by approximately 3.1° C.

It is understood that in the display device according to the exemplary embodiment, the heat dissipation to the outside through the heat dissipation fin is increased as compared with the display device of the comparative embodiment. Further, the temperature is also reduced in the middle and an upper end of the display panel other than the lower end of the display panel in which the heat generating unit is disposed.

The present disclosure may be also applied when the cover shield and the cover bottom are integrated, which will be described in more detail with reference to the following drawings.

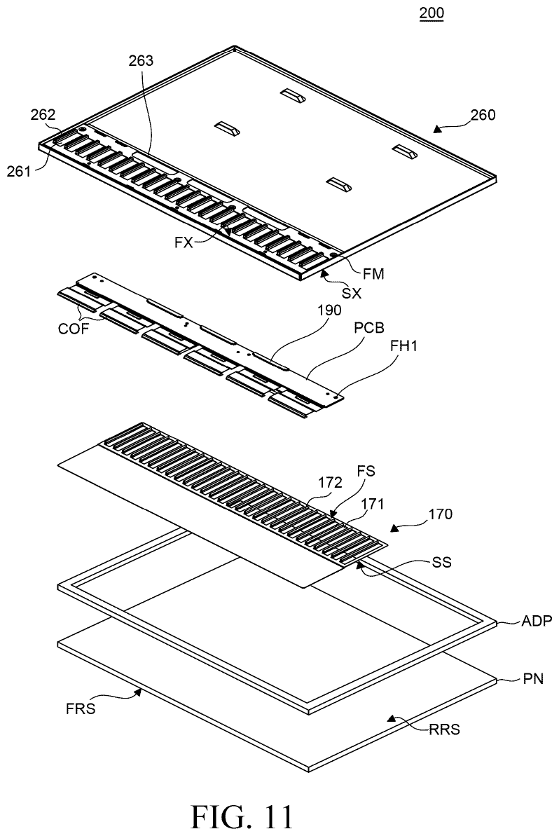

FIG. 11 is an exploded perspective view of a display device according to another exemplary embodiment of the present disclosure.

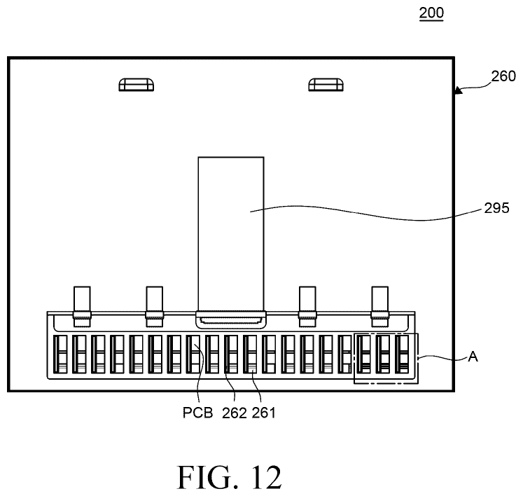

FIG. 12 is a rear view of a display device according to another exemplary embodiment of the present disclosure.

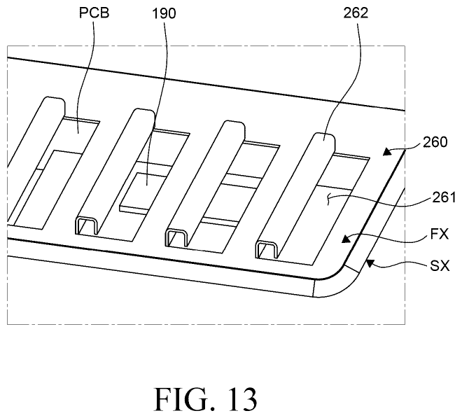

FIG. 13 is an enlarged perspective view of a part A of FIG. 12.

As the same as described above, a surface directed to a lower side in FIG. 11 corresponds to a front surface FRS of the display panel PN on which an image is displayed and a surface directed to an upper side corresponds to a rear surface RRS of the display panel PN.

A display device 200 according to another exemplary embodiment of the present disclosure of FIGS. 11 to 13 has a cover bottom 260 having a different configuration from that of the display device 100 according to the exemplary embodiment of the present disclosure of FIGS. 5 to 8. The other configurations are substantially the same so that a redundant description will be omitted.

Referring to FIGS. 11 to 13, the display device 200 of another exemplary embodiment of the present disclosure may include a display panel PN, an adhesive member ADP, a cover bottom 260, a plate bottom 170, and a printed circuit board PCB.

A plurality of flexible films COF may be bonded onto a rear surface of the display panel PN.

The printed circuit board PCB may be electrically connected to the plurality of flexible films COF.

The printed circuit board PCB may include a first fastening hole FH1. For example, a fastening member FM is inserted into the first fastening hole FH1 formed in the printed circuit board PCB so that the printed circuit board PCB and the plate bottom 170 and the cover bottom 260 may be fastened with each other, but is not limited thereto.

A cover bottom 260 may be disposed on a rear surface of the display panel PN.

The cover bottom 260 may support and protect the display panel PN from the rear surface of the display panel PN. The cover bottom 260 may be formed of a material having a rigidity and a high thermal conductivity and for example, may be formed of a metal material such as iron (Fe), copper (Cu), aluminum (Al), zinc (Zn), silver (Ag), gold (Au), steel use stainless (SUS), or invar, or a plastic material.

A plurality of second vent holes 261 and a plurality of second heat dissipation fins 262 may be disposed at the lower end of the cover bottom 260, like the cover shield described above.

Further, the plurality of flexible films COF and the printed circuit board PCB may be disposed at the lower end of the cover bottom 260 so as to correspond thereto. For example, the plurality of flexible films COF may be bonded in an area adjacent to one edge of the display panel PN and the plurality of flexible films COF and the printed circuit board PCB may be disposed at the lower end of the cover bottom 260 so as to correspond thereto.

Further, the plate bottom 170 may be disposed on the printed circuit board PCB. The plate bottom 170 may support the printed circuit board PCB disposed on the cover bottom 260.

The plate bottom 170 may disperse and dissipate the heat generated in the printed circuit board PCB. The plate bottom 170 does not allow the printed circuit board PCB to be in direct contact with the display panel PN to reduce or minimize the concentration of the heat of the printed circuit board PCB on a specific area of the display panel PN. In the meantime, the printed circuit board PCB includes a plurality of components and among the components, an IC chip 190 which generates a lot of heat may be disposed and this part may form a heat generating unit.

Even though it is not illustrated, the plate bottom 170 may include a fastening unit. At this time, the fastening unit is a part to which the fastening member FM passing through the first fastening hole FH1 of the printed circuit board is coupled. For example, the fastening member FM is coupled to the fastening unit to fix the plate bottom 170 and the printed circuit board PCB to each other.

A plurality of first vent holes 171 and a plurality of first heat dissipation fins 172 for heat dissipation may be provided in a part of the plate bottom 170. The plurality of first vent holes 171 and the plurality of first heat dissipation fins 172 may serve to discharge heat of the printed circuit board PCB, specifically, the IC chip 190 which generates a lot of heat, to the outside. The IC chip 190 may be electrically connected to an FFC cable 295.

For example, the plurality of first vent holes 171 may be disposed along the edge of the plate bottom 170. Further, the plurality of first vent holes 171 may be disposed along the edge of the plate bottom 170 to be perpendicular to the edge of the plate bottom 170.

As described above, the plurality of first vent holes 171 may be configured by an opening cut while forming the plurality of first heat dissipation fins 172. That is, the first heat dissipation fin 172 may be formed by cutting and bending a part of the plate bottom 170. Therefore, when the plurality of first heat dissipation fins 172 is formed, the plurality of first vent holes 171 may be formed in a part in which the plate bottom 170 is cut. Therefore, the first heat dissipation fin 172 may be disposed on the edge of the first vent hole 171. For example, the first heat dissipation fin 172 may be disposed on the edge which is perpendicular to the edge of the plate bottom 170, among edges of the first vent holes 171.

Even though in FIG. 11, it is illustrated that the first heat dissipation fin 172 is bent in a U shape toward the inside of the first vent hole 171, the present disclosure is not limited thereto and the first heat dissipation fin 172 may also be bent in a U shape toward the outside of the first vent hole 171.

In the meantime, as described above, a plurality of second vent holes 261 and a plurality of second heat dissipation fins 262 may be disposed at the lower end of the cover bottom 260, like the cover shield described above.

The cover bottom 260 according to another exemplary embodiment of the present disclosure may serve to not only support and protect the display panel PN but also protect the printed circuit board PCB from the external impact. That is, the cover bottom 260 according to another exemplary embodiment of the present disclosure may be integrally formed with the cover shield described above.

The cover bottom 260 may include a plurality of second vent holes 261. For example, the plurality of second vent holes 261 may be disposed in the most area of the lower end of the cover bottom 260. The plurality of second vent holes 261 is formed to dissipate the heat generated in the printed circuit board PCB to the outside of the cover bottom 260. The IC chip 190 which generates a lot of heat, among the plurality of components of the printed circuit board PCB, may be exposed from the cover bottom 260 through a third opening 263.

The cover bottom 260 may include a plurality of second heat dissipation fins 262.

As described above, for example, the plurality of second vent holes 261 may be configured by an opening cut while forming the plurality of second heat dissipation fins 262. The second heat dissipation fin 262 may be formed by cutting and bending a part of the cover bottom 260. Therefore, when the plurality of second heat dissipation fins 262 is formed, the plurality of second vent holes 261 may be formed in a part in which the cover bottom 260 is cut. Therefore, the second heat dissipation fin 262 may be disposed on the edge of the second vent hole 261. For example, the second heat dissipation fin 262 may be disposed on the edge which is perpendicular to the edge of the cover bottom 260, among edges of the second vent holes 261.

Even though in FIG. 11, it is illustrated that the second heat dissipation fin 262 is bent in a U shape toward the inside of the second vent hole 261, the present disclosure is not limited thereto and the second heat dissipation fin 262 may also be bent in a U shape toward the outside of the second vent hole 261.

The exemplary embodiments of the present disclosure can also be described as follows:

According to an aspect of the present disclosure, there is provided a display device. The display device comprises a display panel in which an active area and a non-active area are defined, a cover bottom which supports the display panel on a rear surface of the display panel, a plate bottom disposed in an opening of the cover bottom, a printed circuit board disposed on a rear surface of the plate bottom and a cover shield disposed to cover the printed circuit board on a rear surface of the cover bottom, wherein a plurality of first vent holes and a plurality of first heat dissipation fins may be disposed in a part of the plate bottom.

In the active area, a plurality of sub pixels and various circuits may be disposed and a light emitting element may be disposed in each of the plurality of sub pixels.

The light emitting element may include a light-emitting diode (LED) and a micro LED.

The display device may further include a gate driver which is mounted between the plurality of sub pixels in a gate in active area (GIA) manner.

The display device may further include a first pad electrode disposed in the non-active area of a front surface of the display panel to transmit a signal to the plurality of sub pixels and a second pad electrode disposed in the non-active area of the rear surface of the display panel to be electrically connected to the flexible film and the printed circuit board.

The display device may further include a side line disposed along a side surface of the display panel to electrically connect the first pad electrode and the second pad electrode.

The display device may further include a plurality of flexible films which is electrically connected to the printed circuit board, and the flexible film and the printed circuit board may pass through the opening to be disposed on the rear surface of the cover bottom.

The plurality of first vent holes and the plurality of first heat dissipation fins may be exposed without being covered by the cover shield.

The first vent hole may be disposed to be perpendicular to an edge of the plate bottom along the edge of the plate bottom.

The first vent hole may be configured by an opening cut while forming the first heat dissipation fin.

The first heat dissipation fin may be disposed on an edge disposed to be perpendicular to an edge of the plate bottom, among edges of the first vent holes.

The first heat dissipation fin may be bent in a U shape toward an inside of the first vent hole.

The first heat dissipation fin may be a part of one edge of the first vent hole which may be bent toward an inside of the first vent hole and may have a “U” shaped cross-section.

The cover shield may include a plurality of second vent holes and a plurality of second heat dissipation fins.

The second vent hole may be configured by an opening cut while forming the second heat dissipation fin.

The second heat dissipation fin may be disposed on an edge disposed to be perpendicular to an edge of the cover shield, among edges of the second vent holes.

The second heat dissipation fin may be a part of one edge of the second vent hole which may be bent toward an inside of the second vent hole and may have a “U” shaped cross-section.

According to another aspect of the present disclosure, there is provided a display device. The display device comprises a display panel in which an active area and a non-active area are defined, a cover bottom which supports the display panel on a rear surface of the display panel, a plate bottom disposed at a lower end of the cover bottom and a printed circuit board disposed on a rear surface of the plate bottom so as to be covered by the lower end of the cover bottom, wherein a plurality of first vent holes and a plurality of first heat dissipation fins may be disposed in a part of the plate bottom and a plurality of second vent holes and a plurality of second heat dissipation fins may be disposed at the lower end of the cover bottom.

The first vent hole may be disposed to be perpendicular to an edge of the plate bottom along the edge of the plate bottom and the second vent hole may be disposed to be perpendicular to an edge of the cover bottom along the edge of the cover bottom.

The first vent hole may be configured by an opening cut while forming the first heat dissipation fin and the second vent hole may be configured by an opening cut while forming the second heat dissipation fin.

The first heat dissipation fin may be disposed on an edge disposed to be perpendicular to an edge of the plate bottom, among edges of the first vent holes and the second heat dissipation fin may be disposed on an edge disposed to be perpendicular to the edge of the plate bottom, among edges of the second vent holes.

The first heat dissipation fin may be a part of one edge of the first vent hole which may be bent toward an inside of the first vent hole and may have a “U” shaped cross-section and the second heat dissipation fin may be a part of one edge of the second vent hole which may be bent toward an inside of the second vent hole and may have a “U” shaped cross-section.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel having an active area and a non-active area adjacent to the non-active area;
a cover bottom which supports the display panel on a rear surface of the display panel, the cover bottom having an opening;
a plate bottom disposed in the opening of the cover bottom;
a printed circuit board disposed on a rear surface of the plate bottom; and
a cover shield disposed to cover the printed circuit board on a rear surface of the cover bottom,
wherein a plurality of first vent holes and a plurality of first heat dissipation fins are disposed in a part of the plate bottom.

2. The display device according to claim 1, wherein in the active area, a plurality of sub pixels and various circuits are disposed and a light emitting element is disposed in each of the plurality of sub pixels.

3. The display device according to claim 2, wherein the light emitting element includes a micro-light emitting diode.

4. The display device according to claim 2, further comprising:
a gate driver which is mounted between the plurality of sub pixels in a gate in active area (GIA) manner.

5. The display device according to claim 2, further comprising:
a first pad electrode disposed in the non-active area of a front surface of the display panel to transmit a signal to the plurality of sub pixels; and
a second pad electrode disposed in the non-active area of the rear surface of the display panel to be electrically connected to a flexible film and the printed circuit board.

6. The display device according to claim 5, further comprising:
a side line disposed along a side surface of the display panel to electrically connect the first pad electrode and the second pad electrode.

7. The display device according to claim 1, further comprising:
a plurality of flexible films which is electrically connected to the printed circuit board,
wherein the flexible film and the printed circuit board pass through the opening to be disposed on the rear surface of the cover bottom.

8. The display device according to claim 1, wherein the plurality of first vent holes and the plurality of first heat dissipation fins are exposed without being covered by the cover shield.

9. The display device according to claim 1, wherein the first vent hole is disposed to be perpendicular to an edge of the plate bottom along the edge of the plate bottom.

10. The display device according to claim 1, wherein the first vent hole is configured by an opening cut while forming the first heat dissipation fin.

11. The display device according to claim 1, wherein the first heat dissipation fin is disposed on an edge disposed to be perpendicular to an edge of the plate bottom, among edges of the first vent holes.

12. The display device according to claim 1, wherein the first heat dissipation fin is bent in a U shape toward an inside of the first vent hole.

13. The display device according to claim 1, wherein the first heat dissipation fin is a part of one edge of the first vent hole which is bent toward an inside of the first vent hole and has a “U” shaped cross-section.

14. The display device according to claim 1, wherein the cover shield includes a plurality of second vent holes and a plurality of second heat dissipation fins.

15. The display device according to claim 14, wherein the second vent hole is configured by an opening cut while forming the second heat dissipation fin.

16. The display device according to claim 14, wherein the second heat dissipation fin is disposed on an edge disposed to be perpendicular to an edge of the cover shield, among edges of the second vent holes.

17. The display device according to claim 1, wherein,
the cover shield includes a third opening, and
an integrated circuit chip included in the printed circuit board is exposed from the cover shield through the third opening.

18. A display device, comprising:
a display panel in which an active area and a non-active area are defined;
a cover bottom which supports the display panel on a rear surface of the display panel;
a plate bottom disposed at a lower end of the cover bottom; and
a printed circuit board disposed on a rear surface of the plate bottom so as to be covered by the lower end of the cover bottom,
wherein a plurality of first vent holes and a plurality of first heat dissipation fins are disposed in a part of the plate bottom and a plurality of second vent holes and a plurality of second heat dissipation fins are disposed at the lower end of the cover bottom.

19. The display device according to claim 18, wherein the first vent hole is disposed to be perpendicular to an edge of the plate bottom along the edge of the plate bottom and the second vent hole is disposed to be perpendicular to an edge of the cover bottom along the edge of the cover bottom.

20. The display device according to claim 18, wherein the first vent hole is configured by an opening cut while forming the first heat dissipation fin and the second vent hole is configured by an opening cut while forming the second heat dissipation fin.

21. The display device according to claim 18, wherein the first heat dissipation fin is disposed on an edge disposed to be perpendicular to an edge of the plate bottom, among edges of the first vent holes and the second heat dissipation fin is disposed on an edge disposed to be perpendicular to the edge of the cover bottom, among edges of the second vent holes.

22. The display device according to claim 18, wherein the first heat dissipation fin is a part of one edge of the first vent hole which is bent toward an inside of the first vent hole and has a “U” shaped cross-section and the second heat dissipation fin is a part of one edge of the second vent hole which is bent toward an inside of the second vent hole and has a “U” shaped cross-section.

23. A tiling display device comprising a plurality of display units, wherein each of the display units comprises the display device according to claim 1.

24. A display device, comprising:
a display panel having an active area and a non-active area adjacent to the active area;
a cover bottom on the display panel;
a plate bottom on the display panel, the plate bottom having a first surface and a second surface opposite the first surface, the plate bottom including:
a plurality of first vent holes, each first vent hole of the plurality of first vent holes extending through the plate bottom from the first surface to the second surface; and
a plurality of first heat dissipation fins, each first heat dissipation fin of the plurality of first heat dissipation fins extending in a direction opposite of the second surface; and
a printed circuit board disposed on the display panel,
wherein the printed circuit board overlaps with the plate bottom from a plan view.

25. The display device of claim 24, wherein the cover bottom is disposed between the plate bottom and the display panel, and
wherein the cover bottom includes an opening, the opening overlapping with the printed circuit board from a plan view.

26. The display device of claim 25, comprising:
cover shield having a first surface and a second surface opposite the first surface, the cover shield including:
a plurality of second vent holes, each second vent hole of the plurality of second vent holes extending through the cover shield from the first surface of the cover shield to the second surface of the cover shield; and
a plurality of second heat dissipation fins, each second heat dissipation fin of the plurality of second heat dissipation fins extending in a direction opposite of the second surface of the cover shield,
wherein the second surface of the cover shield faces the first surface of the plate bottom.

27. The display device of claim 26, wherein the cover shield overlaps with the printed circuit board from a plan view such that the plurality of second vent holes exposes at least a portion of the printed circuit board.

28. The display device of claim 26, wherein the cover shield includes at least one opening, and
wherein the at least one opening of the cover shield is configured to overlap with the printed circuit board where an integrated circuit chip is located from a plan view.

29. The display device of claim 24, wherein the plate bottom is disposed between the cover bottom and the display panel.

30. The display device of claim 29, wherein the cover bottom includes a first surface and a second surface opposite the first surface,
wherein the cover bottom includes:
a plurality of second vent holes, each second vent hole of the plurality of second vent holes extending through the cover bottom from the first surface of the cover bottom to the second surface of the cover bottom; and
a plurality of second heat dissipation fins, each second heat dissipation fin of the plurality of second heat dissipation fins extending in a direction opposite of the second surface of the cover bottom,
wherein the second surface of the cover bottom faces the first surface of the plate bottom.

31. The display device of claim 30, wherein the cover bottom overlaps with the printed circuit board from a plan view such that the plurality of second vent holes exposes at least a portion of the printed circuit board.
